(19) United States
(12) Patent Application Publication
(10) Pub. No.: US 2026/0178107 A1
(43) Pub. Date: Jun. 25, 2026

(54) Dynamic Gated Dual-Pathway Processing Architecture for Regulating High-Fidelity Computation Based on Cumulative Resource Cost

(71) Applicant: Darren Christopher Tindale, North Vancouver (CA)

(72) Inventor: Darren Christopher Tindale, North Vancouver (CA)

(21) Appl. No.: 19/458,870

(22) Filed: Jan. 25, 2026

Related U.S. Application Data
(60) Provisional application No. 63/965,046, filed on Jan. 21, 2026.

(51) Int. Cl. G06F 1/3287; G06F 1/3203; G06F 9/38; G06F 9/48; G06F 9/50; G06F 30/392; G06F 30/394

(52) U.S. Cl. CPC G06F 1/3287; G06F 1/3203; G06F 9/3851; G06F 9/3877; G06F 9/4881; G06F 9/505; G06F 30/392; G06F 30/394

(57) ABSTRACT

A dynamic control architecture for regulating high-fidelity information processing during runtime execution is disclosed. The system bifurcates processing into a first pathway configured to generate a low-latency, low-cost reference representation and a second pathway configured to generate a higher-fidelity representation that incurs greater computational, energetic, or temporal cost. An Executive Gate selectively permits, suppresses, or terminates execution or propagation of the higher-fidelity pathway based on control signals generated by a feedback controller. The feedback controller integrates cumulative resource expenditure over a bounded processing episode and evaluates representational divergence between outputs of the first and second pathways. When cumulative metrics exceed one or more thresholds, inhibitory control is applied to suppress continuation of high-fidelity processing. The architecture supports episodic, reversible gating without erasing stored representations and is applicable to software systems, hardware implementations, integrated circuits, neuromorphic devices, and conceptual or neuro-inspired models.

### I. FIELD OF THE INVENTION

The present invention relates generally to computational architectures, systems, and methods for regulating execution of high-fidelity information processing operations. More particularly, the invention relates to dynamic control mechanisms that selectively permit, suppress, delay, attenuate, or terminate higher-cost, higher-fidelity computation during runtime execution based on cumulative resource expenditure and representational divergence relative to a lower-cost reference representation. In various embodiments, the invention applies to, and may be implemented in, one or more of: digital hardware, integrated circuits, system-on-chip (SoC) designs, field-programmable gate arrays (FPGAs), neuromorphic devices, general-purpose processors, graphics processing units (GPUs), and software systems including artificial neural networks, transformers, computational graphs, and runtime execution pipelines. The invention further relates to control logic implementing temporally structured gating signals and feedback-based governance that condition initiation and/or continuation of high-fidelity computation on integrated resource cost and stability metrics determined during a bounded processing episode. The invention may additionally be described using optional neuro-inspired or conceptual biological analogs to illustrate the disclosed control principles, without requiring implementation using biological structures, physiological mechanisms, or oscillatory signaling.

### II. BACKGROUND OF THE INVENTION

Modern computational systems increasingly rely on high-fidelity information processing to generate detailed, context-sensitive, or stimulus-specific outputs. Such high-fidelity processing is employed in a wide range of applications, including artificial intelligence inference, neural network execution, data analysis pipelines, signal processing systems, and memory or retrieval operations. While high-fidelity computation can improve output precision, it typically incurs substantially greater computational, energetic, and temporal cost than lower-resolution or approximate processing. To manage this trade-off, many systems employ simplified representations, approximations, or heuristic shortcuts to reduce latency and resource consumption. These approaches, however, are generally static or predetermined and do not dynamically regulate the initiation or continuation of high-fidelity computation during runtime execution based on evolving system state. As a result, existing systems frequently execute high-cost computation even when such computation yields diminishing returns, unstable outputs, or internally inconsistent representations. In artificial intelligence and machine learning systems, unregulated high-fidelity processing can lead to excessive energy consumption, inefficient use of hardware resources, and propagation of unstable or divergent outputs. In particular, extended or unconstrained execution of high-fidelity pathways may increase the likelihood of internally inconsistent outputs, hallucinated content, or representational drift when higher-precision computation diverges from lower-cost baseline representations. Existing mitigation techniques, such as training-time regularization, confidence thresholds, or post hoc filtering, do not provide fine-grained, runtime control over whether high-fidelity computation should continue once initiated. In hardware and integrated circuit designs, power-management techniques such as clock gating, power gating, or dynamic voltage and frequency scaling are commonly employed to reduce energy consumption. However, such techniques are typically driven by instantaneous load, thermal conditions, or static scheduling policies rather than by cumulative resource expenditure integrated over a processing episode. Moreover, existing hardware control mechanisms generally do not account for representational stability or divergence between alternative computation paths when making gating decisions. In biological and cognitive systems, empirical evidence indicates that high-fidelity sensory or mnemonic representations may persist over long durations, yet access to such representations is selectively regulated rather than continuously expressed. Classical models often attribute apparent loss of detail to decay or interference; however, accumulating evidence suggests that selective access control plays a significant role in regulating when detailed representations are reinstated or suppressed. Dysregulation of such access control mechanisms has been implicated in cognitive overload, intrusive recollection, hallucinations, and impaired executive control. While these observations motivate biologically inspired computational models, existing systems lack a unified architectural framework that translates such principles into general-purpose, implementation-independent control mechanisms. Across software, hardware, and conceptual biological models, prior art fails to provide an integrated architecture that dynamically governs high-fidelity computation based on (i) cumulative resource cost accrued during a bounded processing episode and (ii) representational divergence relative to a lower-cost reference representation. In particular, prior systems do not provide mechanisms that condition continuation of high-fidelity computation on integrated cost and stability metrics evaluated during runtime execution, rather than relying solely on instantaneous thresholds, training-time constraints, or static execution graphs. Accordingly, there exists a need for systems and methods that selectively regulate initiation and continuation of high-fidelity computation using feedback-driven control logic that accounts for cumulative resource expenditure and internal representational agreement. Such systems should be applicable across software, hardware, integrated circuit, neuromorphic, and hybrid implementations, and should enable graded, episodic, and reversible suppression of high-fidelity processing without erasing underlying representations or requiring retraining, recompilation, or redesign of the computational substrate.

### III. SUMMARY OF THE INVENTION

The present invention provides a dynamic control architecture for regulating high-fidelity information processing during runtime execution. The architecture selectively governs initiation and continuation of higher-cost, higher-fidelity computation based on integrated system state evaluated over a bounded processing episode. In particular, the invention conditions access to high-fidelity computation on cumulative resource expenditure and representational divergence relative to a lower-cost reference representation, thereby improving efficiency, stability, and control across a wide range of computational systems. In one aspect, the invention comprises a dual-pathway processing configuration including a first pathway configured to generate a low-latency, low-cost reference representation and a second pathway configured to generate a higher-fidelity representation that incurs greater computational, energetic, or temporal cost. The second pathway is inactive or suppressed by default and is selectively enabled only when permitted by a control mechanism. The first pathway may generate the reference representation solely for internal control purposes and need not provide a final output or persistently stored representation. An Executive Gate is operatively coupled to the second pathway and is positioned to regulate execution or propagation of high-fidelity computation. The Executive Gate is configured to selectively permit, suppress, delay, attenuate, or terminate high-fidelity processing during a processing episode. In embodiments, the Executive Gate may be implemented using hardware gating logic, software conditional execution, masked computation, scheduling control, or equivalent mechanisms that regulate access to resource-intensive computation. A Sequential-Tax Governor operates as a feedback controller that monitors system state during runtime execution. The Sequential-Tax Governor integrates cumulative resource expenditure associated with high-fidelity computation over a bounded processing episode. Such resource expenditure may include energy consumption, operation counts, memory accesses, bandwidth usage, latency, or other cost metrics observable in hardware or software. The Sequential-Tax Governor further determines or receives a representational divergence metric indicative of the degree of difference between the high-fidelity representation produced by the second pathway and the reference representation produced by the first pathway. Based on the integrated cumulative resource expenditure and the representational divergence metric, the Sequential-Tax Governor dynamically modulates inhibitory control applied to the Executive Gate. When cumulative cost and/or representational divergence exceed one or more thresholds, the Sequential-Tax Governor asserts a control signal that causes the Executive Gate to suppress or terminate continuation of high-fidelity computation. Conversely, when system conditions permit, the Executive Gate may be transiently reopened to allow renewed high-fidelity processing under controlled conditions. In embodiments, the control applied by the Executive Gate is temporally structured, such that high-fidelity computation is permitted only during selective access windows and is subject to veto or suppression within those windows based on cumulative system state. This enables graded, episodic, and reversible access to high-fidelity processing rather than binary or static enablement. The disclosed architecture operates during runtime execution, inference, recall, generation, or context-maintenance operations and does not require retraining, recompilation, or modification of learned parameters as a condition of operation. Control decisions are based on integrated metrics evaluated during execution rather than on instantaneous confidence scores, static thresholds, or training-time regularization constraints. The invention is applicable to a wide range of implementations, including software systems, artificial neural networks, integrated circuits, system-on-chip designs, neuromorphic devices, and hybrid hardware-software systems. Optional neuro-inspired or conceptual biological analogs may be used to illustrate the disclosed control principles without requiring implementation using biological substrates, physiological mechanisms, or oscillatory signaling. By selectively regulating continuation of high-fidelity computation based on cumulative resource cost and representational divergence, the invention reduces unnecessary resource expenditure, limits propagation of unstable or divergent representations, and improves overall system efficiency and stability while preserving availability of lower-cost reference processing.

### IV. TECHNICAL DEFINITIONS & FUNCTIONAL EQUIVALENTS

This section provides functional, structural, and operational definitions of key elements of the invention to satisfy enablement, written description, and best-mode requirements across multiple implementation domains. The definitions are intended to clarify the scope of the invention without limiting the disclosed control mechanisms to any particular technology, architecture, or physical realization unless expressly recited in the claims. Unless otherwise indicated, the terms defined herein apply to hardware, software, integrated circuit, neuromorphic, and hybrid embodiments of the invention.

### IV.1 Executive Gate (EG)

### Definition

The Executive Gate (EG) is a control mechanism configured to regulate whether execution or propagation of high-fidelity computation is permitted to occur. The Executive Gate operates during runtime execution to selectively permit, suppress, delay, attenuate, or terminate high-fidelity processing based on control signals generated during a bounded processing episode.

### Functional Role:

Controls initiation and/or continuation of high-fidelity computation
Enforces default suppression of high-cost processing
Enables selective, episodic, and reversible access to high-fidelity computation

### Hardware Functional Equivalents:

Clock-gating integrated cells
Register-enable logic
Tri-state buffers
Power-gating elements
Instruction-issue or execution-enable circuitry

### Software Functional Equivalents:

Conditional execution branches
Gating layers or operators
Masked computation nodes
Runtime schedulers or dispatch controls

The Executive Gate need not be implemented as a discrete module and may be distributed across control logic, scheduling mechanisms, or execution pipelines, provided it performs the gated control functions described herein.

### IV.2 Inhibitory Mask

### Definition

An inhibitory mask is a control signal, data structure, or dynamic parameter set that suppresses, attenuates, delays, or vetoes execution or propagation of high-fidelity computation. The inhibitory mask functions in conjunction with the Executive Gate to enforce control over high-fidelity processing during runtime execution.

### Operational Characteristics:

May be binary or graded.
May be applied continuously or episodically
May vary dynamically based on system state

### Hardware Functional Equivalents:

Clock-disable signals
Power-disable signals
Memory-access suppression lines

### Software Functional Equivalents:

Sparse attention masks
Activation-zeroing operators
Conditional bypass logic

The inhibitory mask does not require oscillatory signaling, frequency-specific timing, or biological mechanisms and may be implemented using event-driven, schedule-based, or state-machine control logic.

### IV.3 Sequential-Tax Governor (STG)

### Definition

The Sequential-Tax Governor (STG) is a feedback controller configured to monitor cumulative system state during a bounded processing episode and to modulate inhibitory control applied to the Executive Gate based on integrated resource expenditure and representational divergence.

### Monitored Quantities:

Energy consumption
Operation counts (e.g., FLOPs)
Memory accesses or bandwidth usage
Execution latency
Representational divergence

### Operational Behavior:

Integrates monitored quantities over time
Evaluates cumulative metrics against thresholds
Generates control signals that modulate or assert inhibitory masking

The STG may condition continuation of high-fidelity computation on representational stability relative to a lower-cost reference representation, such that high-fidelity processing proceeds only while divergence remains within acceptable bounds.

### IV.4 Representational Divergence

### Definition

Representational divergence is a measure of difference between a higher-fidelity representation produced by a high-fidelity pathway and a lower-cost reference representation produced by a first pathway. Representational divergence provides an internal stability or agreement metric used for gating decisions.

### Non-Limiting Examples of Metrics:

Cosine distance
Euclidean distance
Kullback-Leibler divergence
Cross-entropy
Thresholded comparison functions

Representational divergence does not require comparison to external ground truth and may be computed at intermediate or final stages of processing.

### IV.5 Cumulative Cost

### Definition

Cumulative cost is the integrated measure of resource expenditure associated with execution of high-fidelity computation over a bounded processing episode. Cumulative cost reflects aggregated system load rather than instantaneous usage.

### Non-Limiting Examples

Energy per operation
Total operations executed
Memory or cache accesses
Bandwidth utilization
Execution time

Cumulative cost may be accumulated, decayed, normalized, or reset between processing episodes according to system design.

### IV.6 Processing Episode

### Definition

A processing episode is a bounded interval of runtime execution during which cumulative cost is integrated and gating decisions are evaluated. A processing episode may include one or more cycles, iterations, tokens, layers, kernels, or time slices. Processing episodes need not correspond to fixed durations and may be dynamically determined based on task boundaries, access windows, or system events.

### IV.7 Functional Equivalence Principle

For purposes of claim interpretation and enablement, the invention encompasses all mechanisms that perform substantially the same control functions as the Executive Gate, Sequential-Tax Governor, inhibitory masking, cumulative cost integration, and representational divergence evaluation, regardless of implementation medium, signal representation, or execution environment. Functional equivalence includes, but is not limited to, implementations in:
Digital hardware
Integrated circuits
Software and runtime execution frameworks
Neuromorphic or hybrid systems

No embodiment is limited to any specific algorithm, circuit topology, signal representation, oscillatory mechanism, or biological substrate unless explicitly recited in the claims.

### IV.8 Global Non-Limiting Statement

References to particular architectures, platforms, metrics, timing schemes, or conceptual biological analogs are provided for illustrative purposes only. Such references do not limit the scope of the invention, which is defined solely by the claims. The disclosed control mechanisms may be implemented using alternative structures, processes, or control strategies that achieve substantially the same gating and governance functions described herein.

### V. BRIEF DESCRIPTION OF THE DRAWINGS

The accompanying drawings illustrate exemplary embodiments of the invention and are provided to facilitate understanding of the disclosed systems and control mechanisms. The drawings are illustrative and non-limiting, and like reference numerals designate like elements throughout the drawings.

FIG. 1—System Architecture Block Diagram

FIG. 1 illustrates a system architecture including an input signal (100), a bifurcation point (102), a first pathway (110) generating a reference representation (112), a second pathway (120), an Executive Gate (130), and a Sequential-Tax Governor (140) configured to generate a veto signal (170) based on representational divergence (150) and resource metrics (160).

FIG. 2—Temporally Structured Gating Signals

FIG. 2 illustrates temporally structured gating signals including an access window (202), an inhibitory mask (204), a resultant gating state (206), cumulative cost (208), and representational divergence (210).

FIG. 3—Sequential-Tax Governor (STG) Flowchart

FIG. 3 illustrates an operational flowchart of a Sequential-Tax Governor including initialization (300), monitoring (304), cumulative integration (310), threshold evaluation (312-314), continuation (316), inhibition (318), and reopening evaluation (322).

FIG. 4—Conceptual Biological/Neuromorphic Embodiment

FIG. 4 illustrates a conceptual embodiment including a Prefrontal Control Module (410), a reinstatement field (420), an Executive Gate (430), cumulative load monitoring (412), and representational divergence (452).

FIG. 5—Hardware Implementation Schematic (Integrated Circuit)

FIG. 5 illustrates a hardware implementation including a primary data bus (500), a low-precision logic block (510), a high-precision logic block (520), an Executive Gate (530), and a hardware governor (540) including an accumulator (542), comparator (544), divergence comparator (560), and threshold (570).

FIG. 6—Timing and Sequence Diagram for Gate Operation

FIG. 6 illustrates a timing and sequence diagram including temporal phases (602, 604, 606), a first pathway (610), a second pathway (620), cumulative cost (630), representational divergence (615), an Executive Gate (650), and a veto signal (670).

FIG. 7—Software Flow Graph/Neural Network Implementation

FIG. 7 illustrates a software implementation including a first software pathway (710), a second software pathway (720), an Executive Gate (730), a runtime monitoring wrapper (740), divergence logic (750), and an inhibitory mask (770).

FIG. 8—Example Use Case: Episodic Retrieval

FIG. 8 illustrates an episodic retrieval example including a query (810), a first pathway (820), cumulative cost (830), a high-fidelity retrieval attempt (840), a second pathway (850), representational divergence (860), and a veto signal (880).

FIG. 9—Optional Conceptual Biological Demonstration

FIG. 9 illustrates a conceptual biological demonstration including a hippocampal complex (910), neocortex (920), prefrontal cortex (930), thalamic reticular nucleus (940), inhibitory bursts (960), cumulative metabolic load (970), and representational divergence (980).

### VI. DETAILED DESCRIPTION OF THE CONTROL MECHANISMS AND EXEMPLARY EMBODIMENTS

This section provides a detailed, operative description of exemplary embodiments of the disclosed dynamic gated dual-pathway processing architecture. The description is presented to enable a person of ordinary skill in the art to make and use the invention across a range of implementation domains, including software systems, digital hardware, integrated circuits, neuromorphic devices, and hybrid platforms. The embodiments described herein are illustrative and non-limiting, and the scope of the invention is defined solely by the claims.

### VI.1 Overview of the Architecture

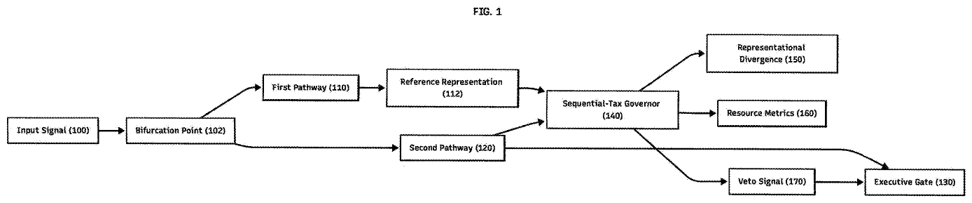

In general, the invention provides a runtime control architecture that selectively regulates initiation and continuation of high-fidelity information processing based on cumulative resource expenditure and representational divergence relative to a lower-cost reference representation. The architecture operates during bounded processing episodes and applies feedback-driven gating to suppress, attenuate, delay, or terminate high-fidelity computation when integrated system state indicates diminishing returns, instability, or excessive cost. As illustrated in FIG. 1, the architecture includes a dual-pathway configuration comprising a first pathway configured to generate a low-latency, low-cost reference representation and a second pathway configured to generate a higher-fidelity representation that incurs greater computational, energetic, or temporal cost. Access to the second pathway is regulated by an Executive Gate under control of a Sequential-Tax Governor.

### VI.2 Dual-Pathway Processing Configuration

The first pathway is configured to produce a reference representation that may comprise a gist-level, approximate, lower-precision, or otherwise lower-resource representation of an input signal. In embodiments, the reference representation is generated solely for internal control purposes and need not be externally output, persistently stored, or labeled as a distinct module. The second pathway is configured to produce a higher-fidelity representation that is more detailed, higher-precision, or more resource-intensive than the output of the first pathway. In embodiments, the second pathway is inactive or suppressed by default and is permitted to execute or propagate only when selectively enabled by the Executive Gate. The first and second pathways may be implemented as distinct branches, execution modes, precision states, scheduling priorities, kernel selections, or resource allocations of a shared execution substrate, provided that a lower-cost reference representation is available and high-fidelity computation is conditionally gated as described herein.

### VI.3 Executive Gate (EG)

The Executive Gate is a control mechanism operatively coupled to the second pathway and positioned at a propagation, execution, or enablement boundary. The Executive Gate selectively permits, suppresses, delays, attenuates, or terminates high-fidelity computation during runtime execution. In hardware embodiments, the Executive Gate may be implemented using clock-gating logic, power-gating elements, register-enable circuitry, multiplexers, tri-state buffers, or equivalent gating structures. In software embodiments, the Executive Gate may be implemented using conditional execution, masked computation, scheduling control, bypass logic, or runtime dispatch control. The Executive Gate may apply binary or graded control and may be reopened or closed multiple times during a processing episode in response to feedback from the Sequential-Tax Governor.

### VI.4 Sequential-Tax Governor (STG)

The Sequential-Tax Governor operates as a feedback controller that monitors system state during a bounded processing episode and modulates inhibitory control applied to the Executive Gate. The STG integrates cumulative resource expenditure associated with execution of high-fidelity computation over time. Monitored resource metrics may include, by way of example and not limitation, energy consumption, operation counts, memory accesses, bandwidth usage, execution latency, or other measurable indicators of computational or operational cost. The STG further determines or receives a representational divergence metric indicative of the degree of difference between a high-fidelity representation produced by the second pathway and the reference representation produced by the first pathway. Representational divergence may be computed using similarity or distance measures and does not require comparison to external ground truth. Based on integrated cumulative cost and representational divergence, the STG dynamically adjusts inhibitory influence applied to the Executive Gate. When one or more thresholds are exceeded, the STG asserts a veto or inhibitory control signal that suppresses or terminates continuation of high-fidelity computation.

### VI.5 Temporally Structured Gating and Processing Episodes

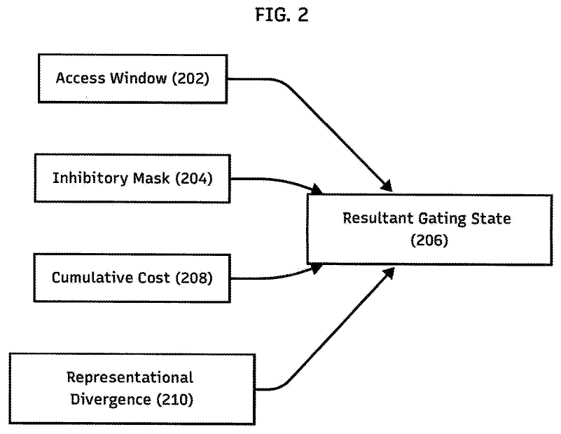

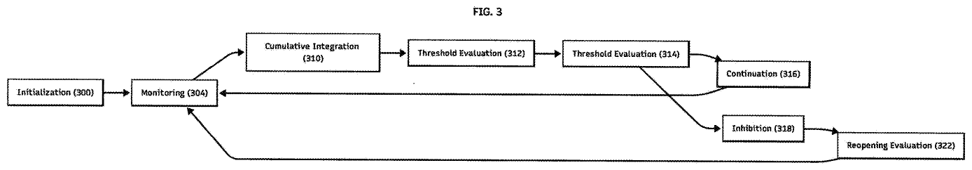

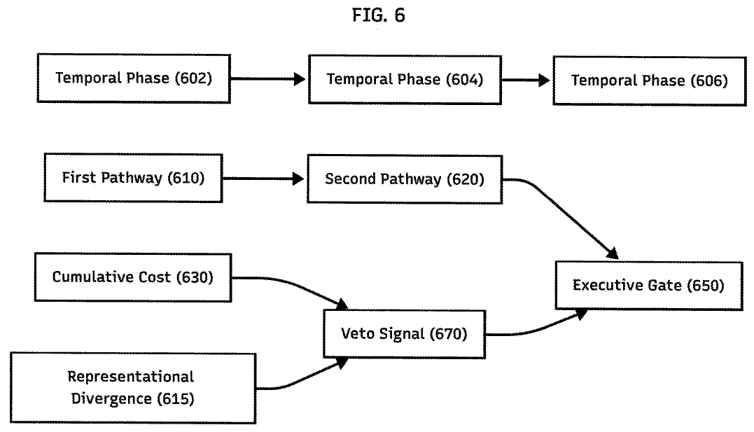

As illustrated in FIGS. 2 and 6, control applied by the Executive Gate and STG may be temporally structured. High-fidelity computation may be permitted only during selective access windows and may be vetoed or suppressed within those windows based on cumulative system state. A processing episode is a bounded interval of runtime execution during which cumulative cost is integrated and gating decisions are evaluated. Processing episodes may correspond to inference passes, retrieval events, generation sequences, context-maintenance intervals, or other task-defined boundaries. Cumulative cost may be reset, decayed, or normalized between episodes according to system design.

### VI.6 Hardware Implementations

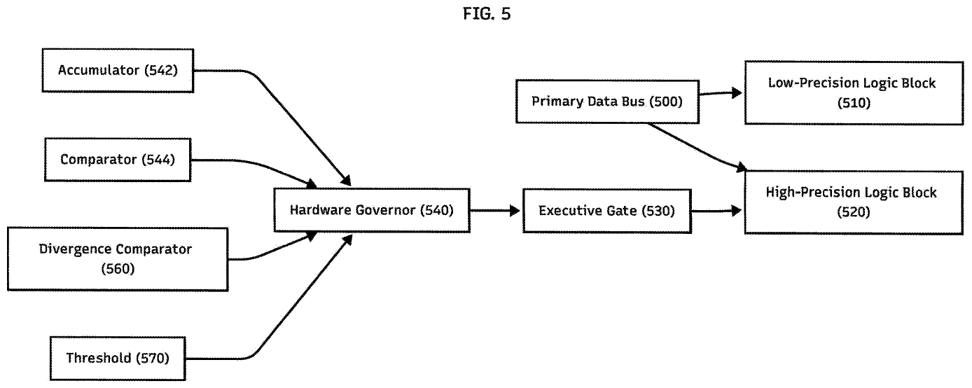

In hardware embodiments, as illustrated in FIG. 5, the architecture may be implemented in an integrated circuit comprising a primary data bus routing data to a low-precision logic block and a high-precision logic block. The Executive Gate controls enablement, clocking, power delivery, or propagation of the high-precision logic block. The Sequential-Tax Governor may be implemented using accumulator registers, comparator circuits, and control logic configured to store and evaluate cumulative cost metrics and representational divergence signals. Assertion of a veto signal physically suppresses switching activity in circuitry associated with high-fidelity computation, thereby reducing energy consumption and improving stability during runtime execution.

### VI.7 Software Implementations

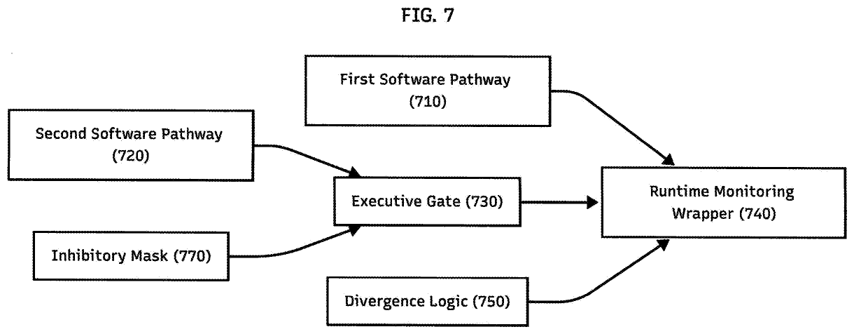

In software embodiments, as illustrated in FIG. 7, the architecture may be implemented within a computational graph, neural network, transformer, or runtime execution pipeline. A first software pathway generates a low-cost reference representation, while a second software pathway generates a higher-fidelity representation when conditionally enabled. The Executive Gate may be implemented as runtime control logic that conditionally suppresses execution of high-fidelity operations. The Sequential-Tax Governor may be implemented as a runtime monitoring module that integrates cumulative computational cost and computes representational divergence during execution. Control decisions are applied during runtime and do not require retraining or modification of learned parameters.

### VI.8 Example Use Case

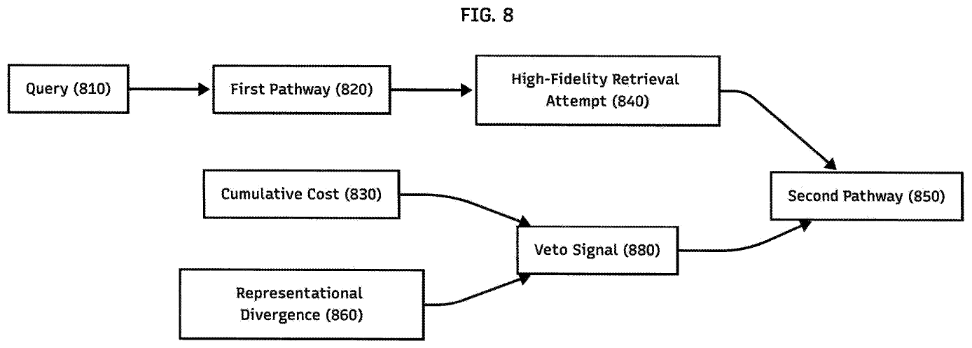

As illustrated in FIG. 8, the architecture may be applied to episodic retrieval or generation scenarios in which a system initially produces a low-latency reference output and selectively permits high-fidelity processing while cumulative cost and representational divergence remain within acceptable limits. When integrated metrics exceed thresholds, high-fidelity processing is suppressed, leaving a stable reference output as the final result for the episode.

### VI.9 Optional Conceptual Biological Demonstrations

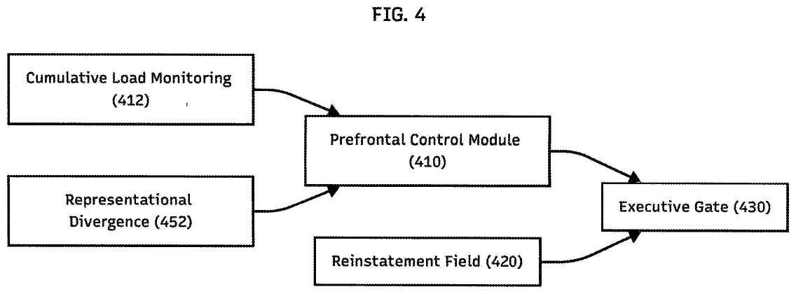

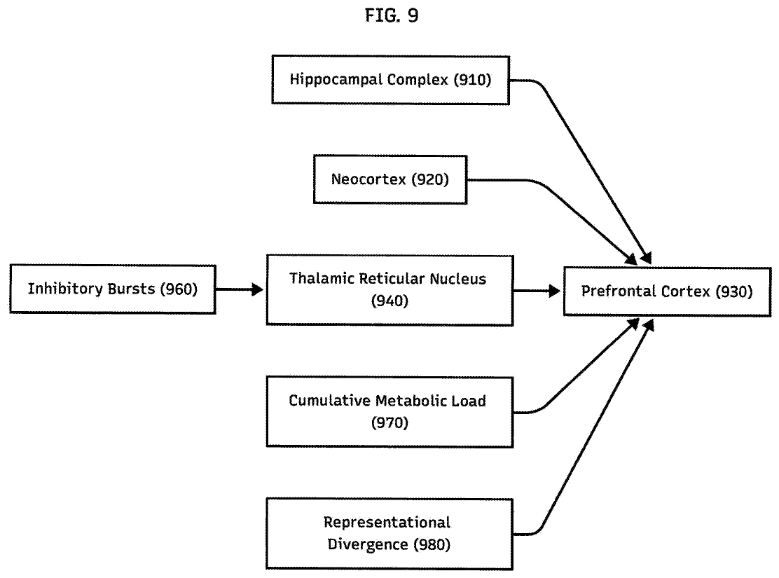

As illustrated in FIGS. 4 and 9, optional conceptual biological or neuro-inspired analogs may be used to illustrate the disclosed control principles. Such demonstrations depict functional analogs of executive gating, cumulative cost monitoring, and divergence-based suppression using illustrative biological structures or oscillatory labels. These analogs are non-limiting and do not require biological substrates, physiological mechanisms, or oscillatory signaling.

### VI.10 Summary of Technical Effects

Across embodiments, the disclosed architecture provides technical effects including reduced resource consumption, controlled execution of high-fidelity computation, prevention of unstable or divergent output propagation, and improved runtime efficiency. By conditioning continuation of high-fidelity computation on cumulative resource expenditure and representational divergence, the invention enables adaptive, episodic, and reversible regulation of computation without erasing underlying representations or requiring retraining or recompilation.

### VII. EXEMPLARY EMBODIMENTS & SCIENTIFIC RATIONALE

This section describes exemplary embodiments of the disclosed dynamic gated dual-pathway processing architecture and provides technical rationale for their operation. The embodiments are illustrative and non-limiting and are provided to demonstrate how the disclosed control mechanisms may be implemented across software systems, hardware systems, integrated circuits, neuromorphic devices, and conceptual or neuro-inspired models. The scope of the invention is defined solely by the claims.

### VII.1 Overview of Exemplary Embodiments

Across embodiments, the invention implements a dual-pathway processing architecture in which a lower-cost reference pathway operates continuously or by default, while a higher-fidelity pathway is selectively initiated and permitted to continue only under control of an Executive Gate governed by a feedback controller. The feedback controller integrates cumulative resource expenditure and evaluates representational divergence to regulate continuation of high-fidelity processing during bounded processing episodes. This architecture enables runtime trade-offs between fidelity, stability, and resource efficiency without erasing stored representations, retraining models, or permanently disabling computation pathways.

### VII.2 Embodiment A: Software-Based Implementation

In a software embodiment, the dual-pathway architecture is implemented within a computational framework such as a neural network, transformer model, inference pipeline, or other execution graph. A first software pathway generates a low-cost reference representation using reduced precision, reduced context length, approximate computation, or sparse execution. A second software pathway generates a higher-fidelity representation using increased precision, extended context, denser computation, or higher-resolution attention mechanisms. Execution of the second pathway is conditionally permitted through an Executive Gate implemented as runtime control logic. A feedback controller integrates cumulative computational cost metrics, such as operation counts, memory usage, or execution latency, and computes representational divergence between outputs of the first and second pathways. When cumulative metrics exceed thresholds, the Executive Gate suppresses continuation of the second pathway during the processing episode.

### Scientific Rationale:

This embodiment reduces unnecessary computation, prevents unstable or divergent output propagation, and improves runtime efficiency without modifying learned parameters. Control decisions are applied during execution and are independent of training-time optimization.

### VII.3 Embodiment B: Hardware or Integrated Circuit Implementation

In a hardware embodiment, the architecture is implemented using digital logic, integrated circuits, or application-specific hardware. Separate logic blocks or execution modes correspond to the low-cost and high-fidelity pathways. A primary bus routes data to both pathways. The Executive Gate is implemented using clock-gating circuitry, power-gating elements, register-enable logic, or equivalent gating structures. A hardware feedback controller integrates cumulative cost metrics using accumulator registers and comparator circuits. When cumulative cost or divergence thresholds are exceeded, the feedback controller asserts a veto signal that suppresses switching activity in circuitry associated with the high-fidelity pathway.

### Scientific Rationale:

This embodiment physically enforces energy-efficient computation by preventing unnecessary switching activity in high-cost logic blocks, improving power efficiency and thermal stability during runtime execution.

### VII.4 Embodiment C: Neuromorphic or Hybrid Systems

In neuromorphic or hybrid embodiments, spiking neural networks or event-driven architectures represent low- and high-fidelity pathways. The Executive Gate is implemented using inhibitory control elements, programmable synaptic gating, or dynamic threshold modulation. The feedback controller integrates recent activity, spike rates, or simulated energy metrics and dynamically adjusts inhibitory influence applied to high-fidelity pathways.

### Scientific Rationale:

This embodiment enables biologically inspired efficiency and stability in event-driven systems while preserving the disclosed control principles independent of biological substrate or physiological constraints.

### VII.5 Embodiment D: Conceptual or Neuro-Inspired Model

In a conceptual embodiment, the disclosed architecture is applied to a simulated or illustrative model of information processing, such as a model of episodic retrieval or sensory reinstatement. Structural elements may be labeled using biological terminology solely for illustrative clarity.

Control logic functionally equivalent to the Executive Gate and feedback controller selectively regulates propagation of high-fidelity representations based on cumulative load and divergence from a reference representation.

### Scientific Rationale:

This embodiment demonstrates the functional advantages of cumulative cost-based gating in systems that exhibit competing demands for speed, fidelity, and stability. Such demonstrations do not require biological implementation and do not limit claim scope.

### VII.6 Cross-Embodiment Consistency

Across all embodiments, the following principles apply:
VII.6.1 High-fidelity processing is inactive or suppressed by default.
VII.6.2 Execution of high-fidelity processing is selectively initiated and conditionally continued.
VII.6.3 Control decisions are based on cumulative resource expenditure rather than instantaneous metrics alone.
VII.6.4 Representational divergence relative to a lower-cost reference representation informs continuation control.
VII.6.5 Suppression of high-fidelity processing is reversible and episodic.

These principles are invariant across software, hardware, integrated circuit, neuromorphic, and conceptual implementations.

### VII.7 Technical Advantages

The disclosed embodiments provide one or more of the following technical advantages:
Reduced energy consumption and resource utilization
Improved runtime stability and output coherence
Prevention of runaway or divergent high-fidelity computation
Scalable control applicable across heterogeneous execution environments
Runtime adaptability without retraining or recompilation

1. A processing architecture for regulating computational resource expenditure, comprising: a first processing pathway configured to generate, during runtime execution, a reference representation using computational resources of a first cost level, the first processing pathway maintaining operation throughout a bounded processing episode;
a second processing pathway configured to generate a higher-fidelity representation using computational resources of a second cost level greater than the first cost level;
a control mechanism configured to regulate execution of the second processing pathway during the bounded processing episode;
wherein the control mechanism computes an integrated evaluation metric comprising cumulative resource expenditure weighted by representational divergence between the higher-fidelity representation and the reference representation;
wherein execution of the second processing pathway is selectively permitted, modulated, or suppressed based on the integrated evaluation metric to maintain operation within predefined resource constraints;
and wherein regulation occurs during runtime execution independent of retraining of the first or second processing pathways.

2. The processing architecture of claim 1, wherein the control mechanism comprises an Executive Gate interposed between the first and second processing pathways.

3. The processing architecture of claim 1, wherein the control mechanism comprises distributed control logic embedded in a runtime scheduler or compiler.

4. The processing architecture of claim 1, wherein representational divergence is computed using at least one of cosine distance, Euclidean distance, Kullback-Leibler divergence, or representational entropy.

5. The processing architecture of claim 1, wherein cumulative resource expenditure comprises at least one of energy consumption, computation cycles, memory bandwidth utilization, or cache miss rate.

6. The processing architecture of claim 1, wherein weighting coefficients of the integrated evaluation metric self-adjust based on historical statistics.

7. The processing architecture of claim 1, wherein suppression of the second processing pathway is reversible upon decay of cumulative resource expenditure below a reopening threshold.

8. The processing architecture of claim 7, wherein the decay comprises exponential decay.

9. The processing architecture of claim 1, further comprising a temporal access window controller establishing alternating access and suppression windows.

10. The processing architecture of claim 9, wherein the windows are phase-locked to neuro-inspired oscillatory patterns including frequencies within 4-8 Hz in biological analog embodiments.

11. The processing architecture of claim 1, wherein the first processing pathway employs lower-precision arithmetic relative to the second processing pathway.

12. The processing architecture of claim 1, wherein the control mechanism inhibits switching activity, memory access, or instruction issue while maintaining computational state.

13. The processing architecture of claim 1, wherein the control mechanism comprises a learned neural controller trained to predict representational instability.

14. The processing architecture of claim 1, wherein the processing episode is bounded by fixed duration, computational budget, or task completion.

15. The processing architecture of claim 1, wherein the processing pathways comprise neural network layers.

16. The processing architecture of claim 15, wherein the neural network layers form part of a transformer architecture with multi-head attention.

17. The processing architecture of claim 1, wherein the control mechanism modulates execution precision or execution depth.

18. The processing architecture of claim 1, wherein the first processing pathway generates the reference representation solely for internal control purposes.

19. The processing architecture of claim 1, wherein the second processing pathway is initially suppressed and conditionally permitted.

20. The processing architecture of claim 1, wherein regulation is implemented in hardware logic, software modules, or hybrid systems.

21. A method of regulating computational resource expenditure in a processing system comprising at least one computational pathway, the method comprising:
deriving a reference state from reduced-resource computation;
monitoring cumulative resource expenditure during higher-resource computation;
evaluating representational stability by comparing the reference state to outputs of the higher-resource computation;
regulating the higher-resource computation based on joint episodic evaluation of cumulative resource expenditure and representational stability;
and asserting a control signal that suppresses execution of computational elements; wherein regulating occurs during runtime without retraining.

22. The method of claim 21, wherein distinct first and second pathways operate in parallel.

23. The method of claim 21, wherein a single adaptive pathway modulates resource expenditure.

24. The method of claim 21, wherein deriving the reference state comprises reduced-precision operations.

25. The method of claim 21, wherein representational stability is evaluated using cosine distance, Kullback-Leibler divergence, predictive uncertainty, or task degradation.

26. The method of claim 21, wherein asserting the control signal comprises clock gating, inhibitory masking, preventing instruction issue, or modulating execution precision.

27. The method of claim 21, wherein the joint episodic evaluation comprises a weighted product of cost and stability.

28. The method of claim 21, wherein the control signal is generated by compiler-inserted instrumentation logic.

29. The method of claim 21, wherein the control signal is generated by a learned controller.

30. The method of claim 21, wherein the processing system comprises a transformer neural network architecture.
